(19) United States
(12) Patent Application Publication
(10) Pub. No.: US 2026/0371629 A1
(43) Pub. Date: Nov. 19, 2026

(54) INSULATED-GATE BIPOLAR TRANSISTOR (IGBT) DEVICE WITH 3D ISOLATION AND METHOD FOR FABRICATING THE SAME

(71) Applicant: Taiwan Semiconductor Manufacturing Company, Ltd., Hsinchu (TW)

(72) Inventor: Hung-Te Lin, Hsinchu (TW)

(21) Appl. No.: 19/754,359

(22) Filed: Jul. 27, 2026

Related U.S. Application Data
(62) Division of application No. 17/744,585, filed on May 13, 2022.

(51) Int. Cl. H10D 12/00; H10D 12/01; H10D 30/66; H10D 62/10; H10D 64/27

(52) U.S. Cl. CPC H10D 12/481; H10D 12/038; H10D 30/668; H10D 62/127; H10D 64/513

(57) ABSTRACT

A method for fabricating an insulated gate bipolar transistor comprises providing a semiconductor substrate having a top surface extending in a horizontal plane. A three-dimensional isolation region comprising a silicon compound is formed having a bottom portion and a sidewall portion. A collector region of a first conductive type is formed disposed on the isolation region. A buffer region of a second conductive type opposite to the first conductive type is formed disposed on the collector region. A drift region of the second conductive type is formed disposed on the buffer region. A body region of the first conductive type is formed disposed in the drift region. At least one source region of the second conductive type is formed disposed in the body region. The isolation region and the top surface enclose the collector, buffer, drift, body, and source regions.

### CROSS-REFERENCES TO RELATED APPLICATIONS

The application is a divisional application of U.S. Non-Provisional patent application Ser. No. 17/744,585 filed May 13, 2022, the entire disclosure of which is incorporated herein by reference.

### FIELD

Embodiments of the present disclosure relate generally to power electronic devices, and more particularly to Insulated Gate Bipolar Transistors (IGBTs).

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

Power semiconductor devices are semiconductor devices often used as switches or rectifiers in power electronics. Power semiconductor devices are also called power devices or, when used in an integrated circuit (IC), power ICs. Power semiconductor devices are found in systems delivering as little as a few tens of milliwatts for a headphone amplifier, up to around a gigawatt in a high voltage direct current transmission line. Some common power semiconductor devices are power Metal-Oxide-Semiconductor Field-Effect Transistors (MOSFETs), power diodes, thyristors, and Insulated Gate Bipolar Transistors (IGBTs).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional diagram illustrating an example IGBT in accordance with some embodiments.

FIG. 1B is a top view of the example IGBT shown in FIG. 1A in accordance with some embodiments.

FIG. 1C is a perspective view of the example IGBT shown in FIG. 1A in accordance with some embodiments.

FIG. 2 is a flowchart diagram illustrating an example method for making an IGBT in accordance with some embodiments.

FIG. 3A is a flowchart diagram illustrating an example of the operation 202 shown in FIG. 2 in accordance with some embodiments.

FIG. 3B is a flowchart diagram illustrating another example of the operation 202 shown in FIG. 2 in accordance with some embodiments.

FIG. 4 is a flowchart diagram illustrating an example of the operation 204 shown in FIG. 2 in accordance with some embodiments.

FIGS. 5A-5N are cross-sectional diagrams illustrating the structure, at various stages, fabricated using the example method shown in FIG. 3A.

FIG. 5O is a cross-sectional diagram illustrating the structure, at one stage, fabricated using the example method shown in FIG. 3B.

FIG. 6A is a cross-sectional diagram illustrating an example IGBT in accordance with some embodiments.

FIG. 6B is a top view of the example IGBT shown in FIG. 6A in accordance with some embodiments.

FIG. 6C is a perspective view of the example IGBT shown in FIG. 6A in accordance with some embodiments.

FIG. 7 is a flowchart diagram illustrating another example of the operation 204 shown in FIG. 2 in accordance with some embodiments.

FIG. 8 is a diagram illustrating a chip 800 in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

An Insulated Gate Bipolar Transistors (IGBT) is a three-terminal power semiconductor device often used as an electronic switch, which combines high efficiency and fast switching. An IGBT can be regarded as an integrated combination of a bipolar transistor and a Metal-Oxide-Semiconductor Field-Effect Transistor (MOSFET). IGBTs have superior on-state characteristics and excellent safe-operating window. IGBTs in integrated circuits are commonly configured as lateral IGBTs (LIGBTs) and vertical IGBTs (VIGBTs).

LIGBTs are fabricated using a planar process sequence to minimize the cost and the complexity of the integrated circuit manufacturing processes. In some implementations, LIGBTs are formed on a silicon-on-insulator (SOI) substrate. However, the use of SOI substrates is expensive, and a large current gain is hard to achieve.

VIGBTs have electrodes on either the top surface or the bottom surface of the chip. Typically, gate and emitter electrodes of a VIGBT are on the top surface, while the collector electrode of a VIGBT is on the bottom surface. VIGBTs can offer a larger current gain than LIGBT due to their vertical structure. The vertical structure, however, is more complicated than that of a LIGBT. The fabrication process of VIGBTs needs wafer thinning processes and thermal processes, which result in a high risk of chip break, high dose implantation, and annealing temperature restrictions.

In accordance with some aspects of the disclosure, embodiments of IGBTs and the method for making them are provided. In one embodiment, an IGBT includes a semiconductor substrate having a top surface 190 extending in horizontal directions, a three-dimensional (3D) isolation region comprising a silicon compound, a collector region disposed on the 3D isolation region, a buffer region disposed on the collector region, a drift region disposed on the buffer region, a body region disposed in the drift region, and at least one source region disposed in the body region. The 3D isolation region 104 includes a bottom portion and a sidewall portion. The sidewall portion extends upwardly from the perimeter of the bottom portion and reaches the top surface of the semiconductor substrate. As such, the 3D isolation region and the top surface of the semiconductor substrate enclose the collector region, the buffer region, the drift region, the body region, and the at least one source region.

Accordingly, the 3D isolation region 104 provides the IGBT with good isolation, without using an expensive SOI substrate like LIGBTs. In addition, as the electrodes (i.e., gate, emitter, and collector) are disposed on the top surface of the semiconductor surface, the drawbacks (e.g., high risk of chip break, high dose implantation, and annealing temperature restrictions) related to the backside processes of VIGBTs can be avoided. The IGBTs disclosed are compatible with other silicon-based process flows.

In one embodiment, the 3D isolation region is made of silicon dioxide. In one implementation, the oxygen of the 3D isolation region is introduced using ion implantation following by an annealing process. In another implementation, the oxygen of the 3D isolation region is introduced using epitaxial growth of a silicon epitaxial layer, during which oxygen is used as a material source as well.

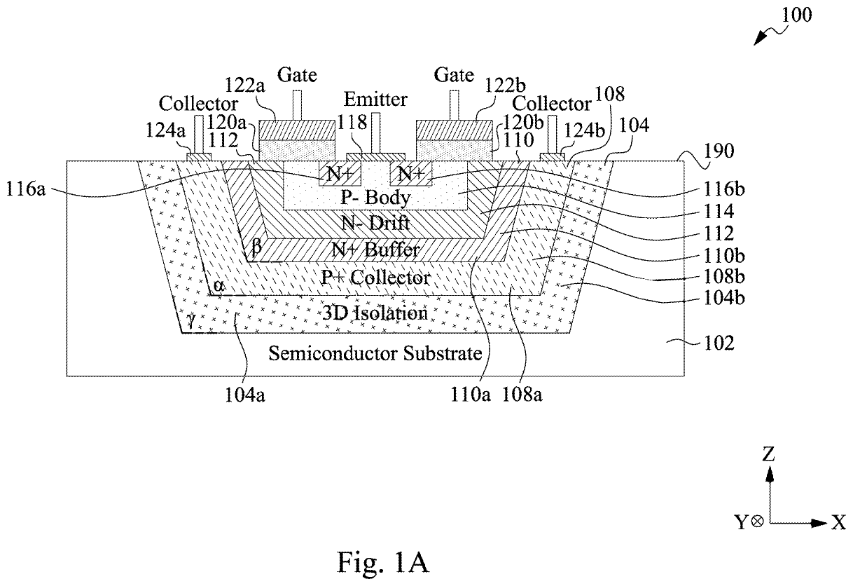

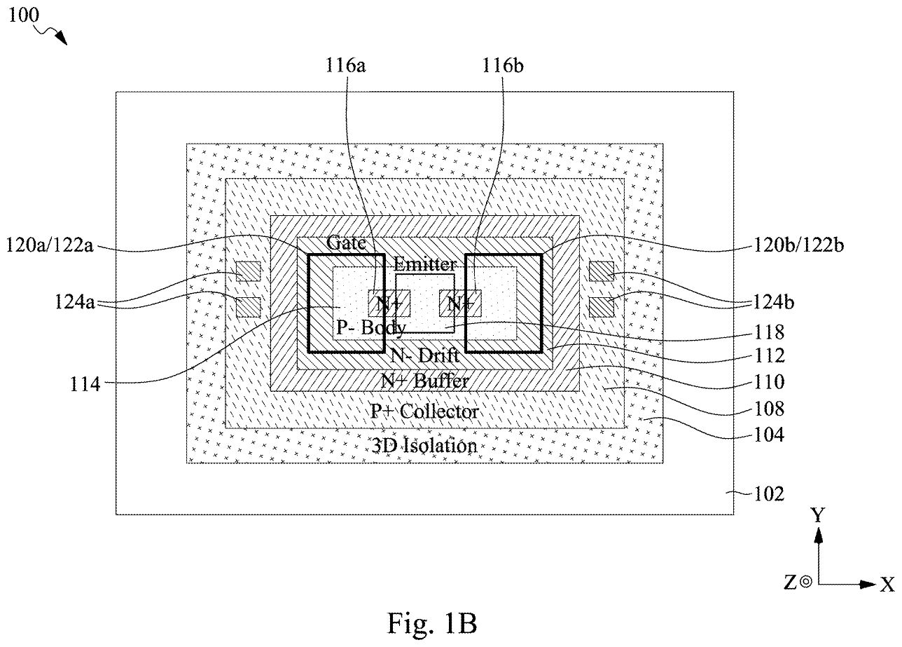

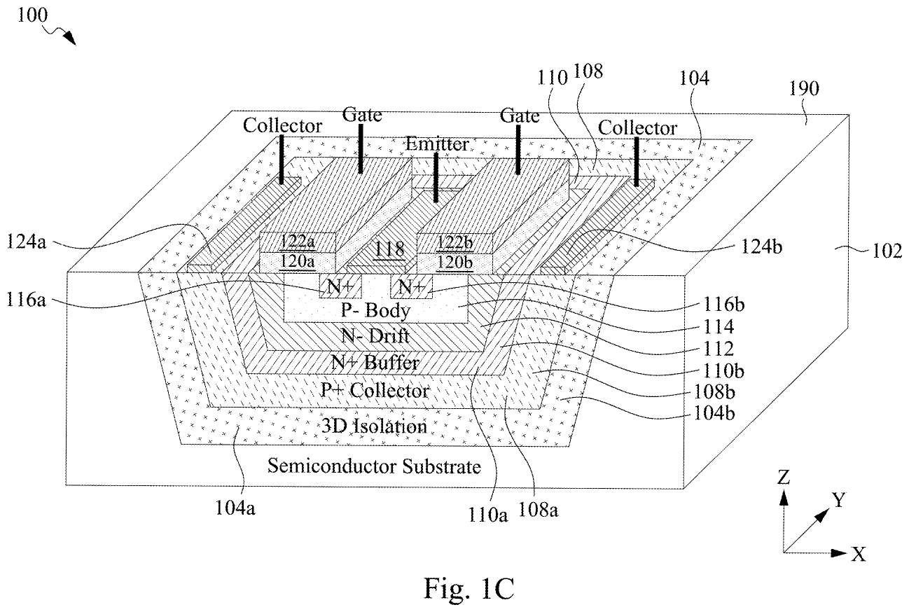

The techniques disclosed here are applicable to both surface-gate IGBTs and trench-gate IGBTs. The techniques disclosed here are applicable to both punch-through IGBTs and non-punch-through IGBTs. Details of the techniques mentioned above will be described below with reference to FIGS. 1A-8.

FIG. 1A is a cross-sectional diagram illustrating an example IGBT 100 in accordance with some embodiments. FIG. 1B is a top view of the example IGBT 100 shown in FIG. 1A in accordance with some embodiments. FIG. 1C is a perspective view of the example IGBT 100 shown in FIG. 1A in accordance with some embodiments. In the example shown in FIGS. 1A-1C, the IGBT 100 includes, among other components, a semiconductor substrate 102, a three-dimensional (3D) isolation region 104, a collector region 108, a buffer region 110, a drift region 112, a body region 114, two source regions 116a and 116b, an emitter electrode 118, two gate dielectric structures 120a and 120b, two gate electrodes 122a and 122b, and two collector electrodes 124a and 124b.

In one implementation, the semiconductor substrate 102 is a (single crystal) silicon substrate. The semiconductor substrate has a top surface 190. The 3D isolation region 104 includes a bottom portion 104a and a sidewall portion 104b. The bottom portion 104a extends in the horizontal plane (i.e., the X-Y plane as shown in FIG. 1A). The bottom portion 104a is disposed on the bottom surface of a trench formed in the semiconductor substrate 102. The bottom portion 104a separates the collector region 108, the buffer region 110, the drift region 112, the body region 114, and the source regions 116a and 116b from the semiconductor substrate 102 in the vertical direction (i.e., the Z-direction shown in FIG. 1A). As shown in FIG. 1C, the bottom portion 104a has a rectangular shape. It should be understood that this is not intended to be limiting, and the bottom portion 104a may have other shapes in other embodiments.

The sidewall portion 104b extends upwardly from the perimeter of the bottom portion 104a and reaches the top surface 190 of semiconductor substrate 102. The sidewall portion 104b and the bottom portion 104a define an angle γ shown in FIG. 1A. In some embodiments, the angle γ is larger than 85 degrees. In one example, the angle γ is 90 degrees. In another example, the angle γ is 100 degrees. In yet another example, the angle γ is 110 degrees. In still another example, the angle γ is 120 degrees. The sidewall portion 104 b is disposed on the sidewalls of the trench formed in the semiconductor substrate 102. The sidewall portion 104b separates the collector region 108, the buffer region 110, the drift region 112, the body region 114, and the source regions 116a and 116b from the semiconductor substrate 102 in the horizontal directions (i.e., the X-direction and the Y-direction shown in FIG. 1A). In the horizontal directions, the sidewall portion 104b encircles the collector region 108, the buffer region 110, the drift region 112, the body region 114, and the source regions 116a and 116b.

As such, the 3D isolation region 104 separates the collector region 108, the buffer region 110, the drift region 112, the body region 114, and the source regions 116a and 116b from the semiconductor substrate 102 in both the vertical direction and the horizontal directions. The 3D isolation region 104 is made of an electrical insulator. In one embodiment, the 3D isolation region 104 is made of silicon dioxide. Accordingly, the separation or isolation is 3D (i.e., in both the vertical direction and the horizontal directions). The 3D isolation region 104 and the top surface 190 of the semiconductor substrate 102 enclose or encapsulate the collector region 108, the buffer region 110, the drift region 112, the body region 114, and the source regions 116a and 116b. Accordingly, the 3D isolation region 104 provides the IGBT 100 with good isolation, without using an expensive SOI substrate.

The 3D isolation region 104 is made of a silicon compound. In one example, the 3D isolation region 104 is made of silicon dioxide. In another example, the 3D isolation region 104 is made of silicon nitride.

The collector region 108 is disposed on the 3D isolation region 104. The collector region 108 includes a bottom portion 108a and a sidewall portion 108b. The bottom portion 108a extends in the horizontal plane (i.e., the X-Y plane as shown in FIG. 1A). The bottom portion 108a is disposed on the bottom portion 104a of the 3D isolation region 104. As shown in FIG. 1C, the bottom portion 108a has a rectangular shape. It should be understood that this is not intended to be limiting, and the bottom portion 108a may have other shapes in other embodiments.

The sidewall portion 108b extends upwardly from the perimeter of the bottom portion 108a and reaches the top surface 190 of semiconductor substrate 102. The sidewall portion 108b and the bottom portion 108a define an angle α shown in FIG. 1A. In some embodiments, the angle α is larger than 85 degrees. In one example, the angle α is 90 degrees. In another example, the angle α is 100 degrees. In yet another example, the angle α is 110 degrees. In still another example, the angle α is 120 degrees. The sidewall portion 108 b is disposed on the sidewall portion 104b of the 3D isolation region 104. Accordingly, the collector region 108 and the top surface 190 enclose or encapsulate the buffer region 110, the drift region 112, the body region 114, and the source regions 116a and 116b.

In one embodiment, the collector region 108 is a doped silicon region. The collector region 108 is of the first conductive type and heavily doped. In the example shown in FIGS. 1A-1C, the collector region 108 is p-type and heavily doped (i.e., p+). Unlike VIGBTs, the collector electrodes 124a and 124b are disposed on the top surface of the sidewall portion 108b of the collector region 108, making the fabrication process easier than that of VIGBTs.

It should be understood that although the collector region 108 is formed on the 3D isolation region 104 in this embodiment shown in FIGS. 1A-1C, this is not intended to be limiting. In another embodiment, a silicon epitaxial layer can be formed on the 3D isolation region 104 before the collector region 108 is formed thereon. In other words, the 3D isolation region 104 and the collector region 108 sandwich a silicon epitaxial layer.

The buffer region 110 is disposed on the collector region 108. The buffer region 110 includes a bottom portion 110a and a sidewall portion 110b. The bottom portion 110a extends in the horizontal plane (i.e., the X-Y plane as shown in FIG. 1A). The bottom portion 110a is disposed on the bottom portion 108a of the collector region 108. As shown in FIG. 1C, the bottom portion 110a has a rectangular shape. It should be understood that this is not intended to be limiting, and the bottom portion 110a may have other shapes in other embodiments.

The sidewall portion 110b extends upwardly from the perimeter of the bottom portion 110a and reaches the top surface 190 of semiconductor substrate 102. The sidewall portion 110b and the bottom portion 110a define an angle β shown in FIG. 1A. In some embodiments, the angle β is larger than 85 degrees. In one example, the angle β is 90 degrees. In another example, the angle β is 100 degrees. In yet another example, the angle β is 110 degrees. In still another example, the angle β is 120 degrees. The sidewall portion 110b is disposed on the sidewall portion 108b of the collector region 108. Accordingly, the buffer region 110 and the top surface 190 enclose or encapsulate the drift region 112, the body region 114, and the source regions 116a and 116b.

It should be understood that in other embodiments, the intersections corresponding to the angles α, β, and γ shown in FIG. 1A may be replaced with round corners. That is, the bottom portion 104a/108a/110a and the sidewall portion 104b/108b/110b define a round corner. In one example, the radius of those round corners is larger than 0.05 μm.

In one example, the device depth (i.e., the distance between the bottom surface of the collector region 108 and the top surface 190 of the semiconductor substrate 102 in the Z-direction) ranges from 2 μm to 200 μm. In one example, the thickness (both in the Z-direction and the X-direction) of the collector region 108 ranges from 0.1 μm to 1 μm. In one example, the thickness (both in the Z-direction and the X-direction) of the buffer region 110 ranges from 0.05 μm to 1 μm. In one example, the thickness (both in the Z-direction and the X-direction) of the 3D isolation region 104 is larger than 0.1 μm. In one example, the distance between the buffer region 110 and the collector electrode 124a or 124b in the X-direction is larger than 0.1 μm. In one example, the distance between the buffer region 110 and the gate electrode 122a or 122b in the X-direction is larger than 0.1 μm. It should be understood that the examples above are exemplary rather than limiting.

In one embodiment, the buffer region 110 is a doped silicon region. The buffer region 110 is of the second conductive type opposite to the first conductive type and heavily doped. In the example shown in FIGS. 1A-1C, the buffer region 110 is n-type and heavily doped (i.e., n+). In the embodiment shown in FIGS. 1A-1C, the IGBT 100 is a punch-through (PT) IGBT, which has better speed and lower on-state voltage than a non-punch-through (NPT) IGBT. In other embodiments, the IGBT may be a non-punch-through (NPT) IGBT, and there is no buffer region between the collector region 108 and the drift region 112.

The drift region 112 is disposed on the buffer region 110. The drift region 112 is disposed on both the bottom portion 110a and the sidewall portion 110b of the buffer region 110. In one embodiment, the drift region 112 is a doped silicon region. The drift region 112 is of the second conductive type and lightly doped. In the example shown in FIGS. 1A-1C, the drift region 112 is n-type and lightly doped (i.e., n−). The drift region 112 serves as the drain of a first Metal-Oxide-Semiconductor Field-Effect Transistors (MOSFET) (the drift region 112 as the drain, the body region 114 as the body, the source region 116a as the source, and the gate electrode 122a as the gate) and the drain of a second MOSFET (the drift region 112 as the drain, the body region 114 as the body, the source region 116b as the source, and the gate electrode 122b as the gate). The drift region 112 also serves as the base of a Bipolar Junction Transistor (BJT) (the collector region 108 as the collector, the drift region 112 as the base, and the body region 114 as the emitter). As a result, the base of the BJT is electrically connected to the drain of the first MOSFET and the drain of the second MOSFET.

The body region 114 is disposed on the drift region 112. The body region 114 is encircled by the drift region 112 in the horizontal directions. In one implementation, the body region 114 is a well formed by ion implantation at an exposed area of the drift region 112. The body region 114 is of the first conductive type and lightly doped. In the example shown in FIGS. 1A-1C, the body region 114 is p-type and lightly doped (i.e., p−). The body region 114 serves as the body of the first MOSFET and the drain of the second MOSFET. The body region 114 also serves as the emitter of the BJT.

The source regions 116a and 116b are disposed in the body region 114. The source regions 116a and 116b are encircled by the body region 114 in the horizontal directions. In one implementation, the source regions 116a and 116b are formed by ion implantation at exposed areas of the body region 114. The source regions 116a and 116b are of the second conductive type and heavily doped. In the example shown in FIGS. 1A-1C, the source regions 116a and 116b are n-type and heavily doped (i.e., n+). The source region 116a serves as the source of the first MOSFET, whereas the source region 116b serves as the source of the second MOSFET.

The emitter electrode 118 is disposed on the top surface (sometimes also referred to as the “front surface”) 190 of the semiconductor substrate 102. The emitter electrode 118 is disposed on a portion of the source region 116a and a portion of the body region 114, therefore connecting the source of the first MOSFET and the emitter of the BJT. Likewise, the emitter electrode 118 is disposed on a portion of the source region 116b and a portion of the body region 114, therefore connecting the source of the second MOSFET and the emitter of the BJT.

The gate dielectric structure 120a is disposed on the top surface 190 of the semiconductor substrate 102, and the gate electrode 122a is disposed on the gate dielectric structure 120a. In one implementation, the gate electrode 122a is made of polysilicon. In another implementation, the gate electrode 122a is made of a metal. In yet another implementation, the gate electrode 122a is made of a metal compound. The gate dielectric structure 120a may comprise one or more dielectrics. In one implementation, the gate dielectric structure 120a is a metal oxide. In another implementation, the gate dielectric structure 120a is a high-κ dielectric. The gate dielectric structure 120a is disposed on a portion of the drift region 112, a portion of the body region 114, and a portion of the source region 116a. When a positive voltage is applied to the gate electrode 122a, it attracts electrons, inducing an n-type conductive channel (i.e., an inversion layer) in the body region 114 that is below the gate dielectric structure 120a. The inversion layer allows electrons to flow between the drift region 112 and the source region 116a.

Likewise, the gate dielectric structure 120b is disposed on the top surface 190 of the semiconductor substrate 102, and the gate electrode 122b is disposed on the gate dielectric structure 120b. In one implementation, the gate electrode 122b is made of polysilicon. In another implementation, the gate electrode 122b is made of a metal. In yet another implementation, the gate electrode 122b is made of a metal compound. The gate dielectric structure 120b may comprise one or more dielectrics. In one implementation, the gate dielectric structure 120b is a metal oxide. In another implementation, the gate dielectric structure 120b is a high-κ dielectric. The gate dielectric structure 120b is disposed on a portion of the drift region 112, a portion of the body region 114, and a portion of the source region 116b. When a positive voltage is applied to the gate electrode 122b, it attracts electrons, inducing an n-type conductive channel (i.e., an inversion layer) in the body region 114 that is below the gate dielectric structure 120b. The inversion layer allows electrons to flow between the drift region 112 and the source region 116b.

Accordingly, the source of the first MOSFET, which is electrically connected to the emitter, is electrically connected to the drain of the first MOSFET, and the source of the second MOSFET, which is electrically connected to the emitter, is electrically connected to the drain of the second MOSFET. As explained above, the base of the BJT also serves as the drain of the first MOSFET and the drain of the second MOSFET. Accordingly, the emitter of the BJT is electrically connected to the base of the BJT through two electrical paths, one being the source region 116a and the inversion layer under the gate dielectric structure 120a and another being the source region 116b and the inversion layer under the gate dielectric structure 120b. The electrons in the heavily doped source regions 116a and 116b flow to the drift region 112.

When the collector electrodes 124a and 124b are properly biased, the electrons in the drift region flow to the collector region 108. As such, there is a current flowing from the collector electrode 124a, through the drift region 112, the inversion layers in the body region 114, and the source region 116a, to the emitter electrode 118, while there is another current flowing from the collector electrode 124b, through the drift region 112, the inversion layers in the body region 114, and the source region 116b, to the emitter electrode 118.

In one example, the IGBT 100 has the following operation voltages. In an on state, when V_{GE} ranges from 0 to 50 volts, V_{CE} ranges from 0 to 50 volts. In an off state, when V_{GE} is 0, V_{CE} ranges from 0 to 500 volts. In another off-state, when V_{CE} is 0, V_{GE} ranges from 0 to 50 Volts.

In one example, the dopant concentration of the collector region 108 ranges from 1×10¹⁵ cm⁻² to 1×10¹⁷ cm⁻²; the dopant concentration of the buffer region 110 ranges from 1×10¹⁵ cm⁻² to 1×10¹⁶ cm⁻²; the dopant concentration of the drift region 112 ranges from 1×10¹² cm⁻² to 1×10¹⁴ cm⁻²; the dopant concentration of the body region 114 ranges from 1×10¹² cm⁻² to 1×10¹⁴ cm⁻²; the dopant concentration of the source regions 116a and 116b ranges from 1×10¹⁵ cm⁻² to 5×10¹⁵ cm⁻². It should be understood that these dopant concentration values are exemplary rather than limiting, and other dopant concentration values can be employed in other examples.

It should be understood that the conductivity type of the collector region 108, the buffer region 110, the drift region 112, the body region 114, and the source regions 116a and 116b can be the opposite to those shown in FIG. 1A in another example.

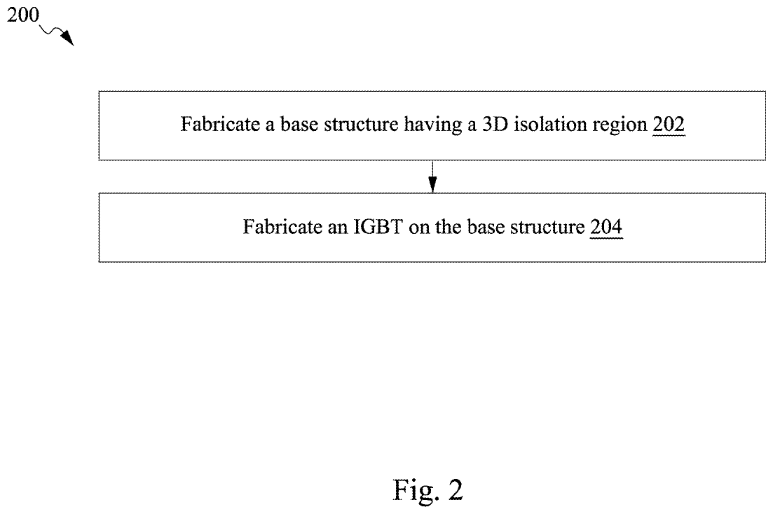

FIG. 2 is a flowchart diagram illustrating an example method 200 for making an IGBT in accordance with some embodiments. The example method 200 includes operation 202 and operation 204. At operation 202, a base structure having a 3D isolation region is fabricated. The base structure is fabricated on a semiconductor substrate (e.g., the semiconductor substrate 102 shown in FIG. 1A). In one implementation, the base structure has a 3D isolation region (e.g., the 3D isolation region 104 shown in FIG. 1A). In one implementation, the base structure also has a collector region (e.g., the collector region 108 shown in FIG. 1A) and a buffer region 110 (e.g., the buffer region 110 shown in FIG. 1A), among other components.

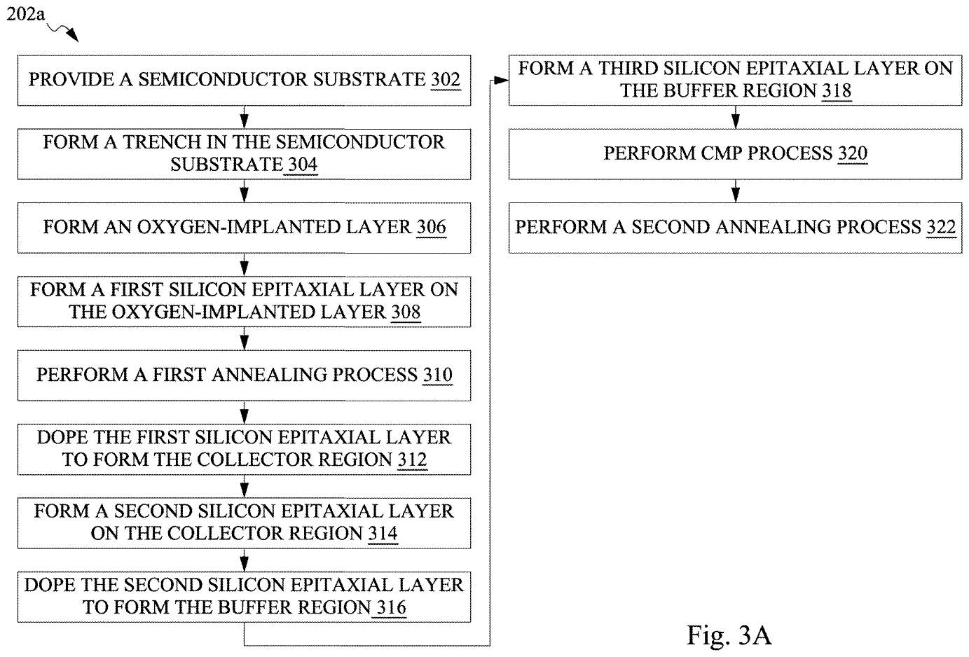

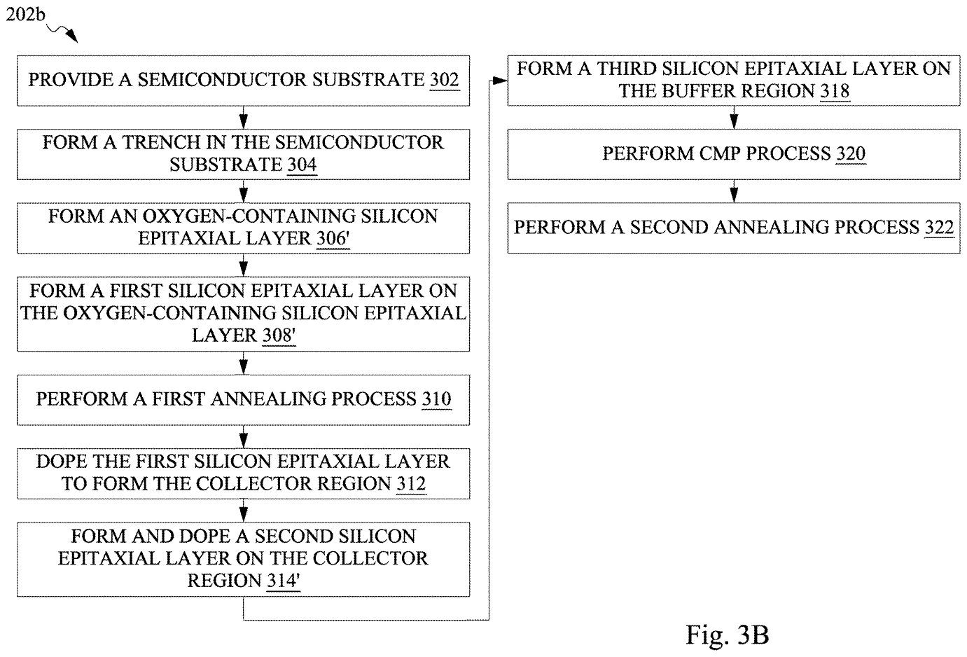

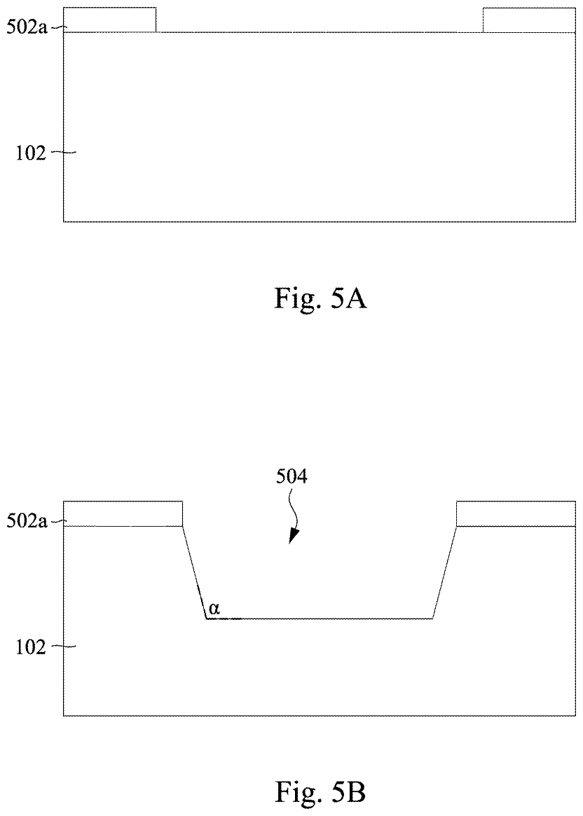

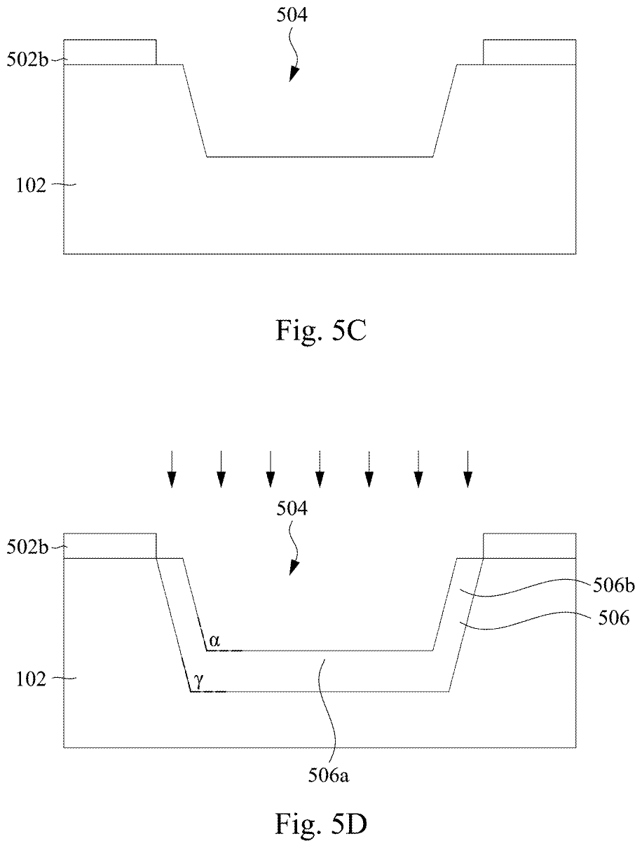

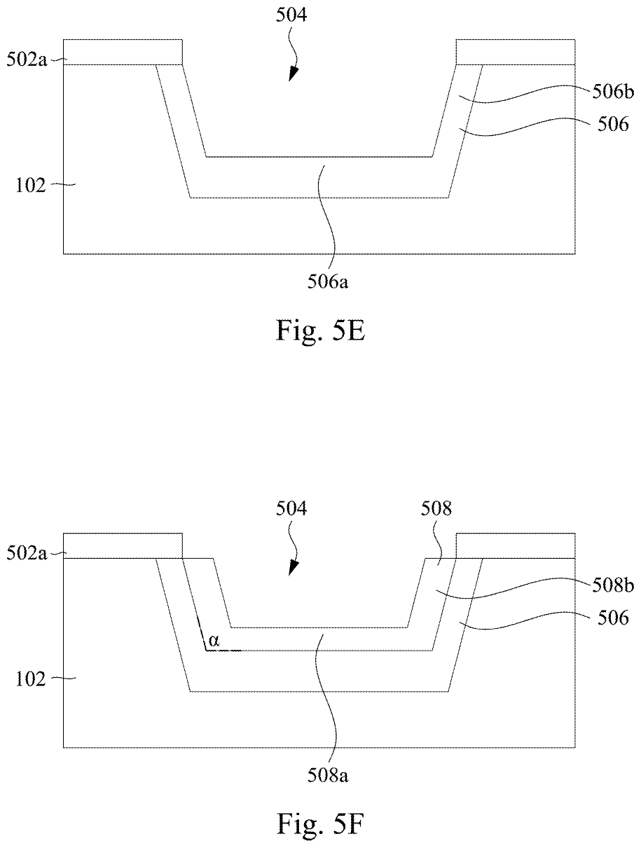

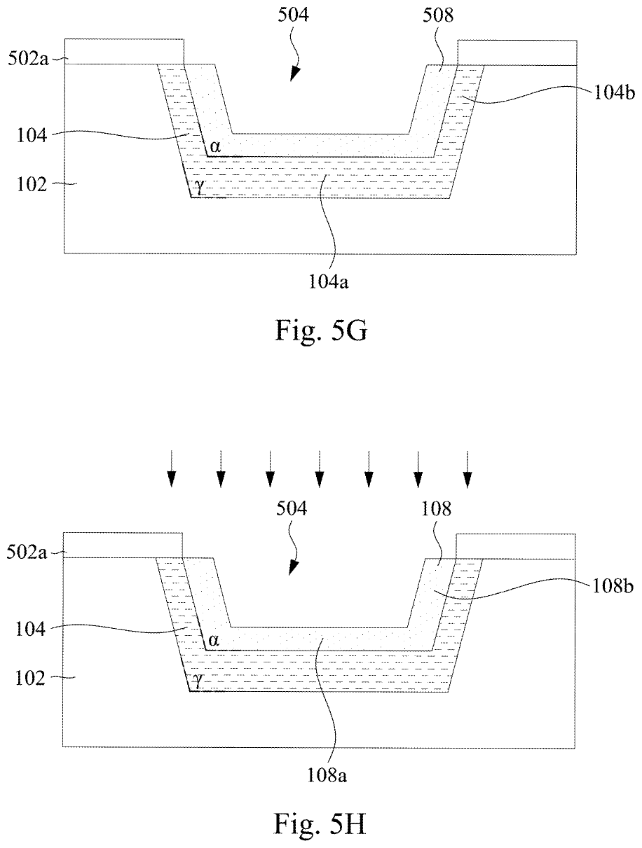

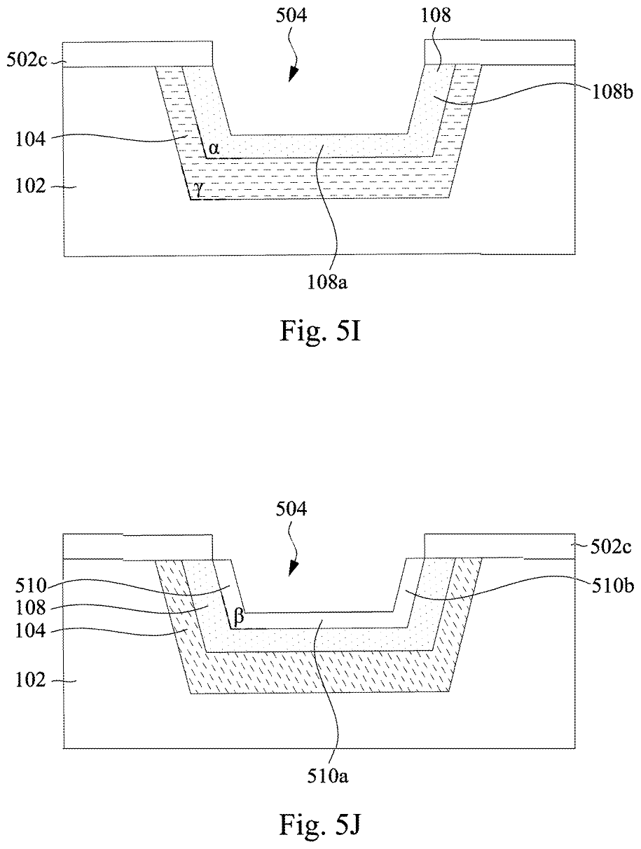

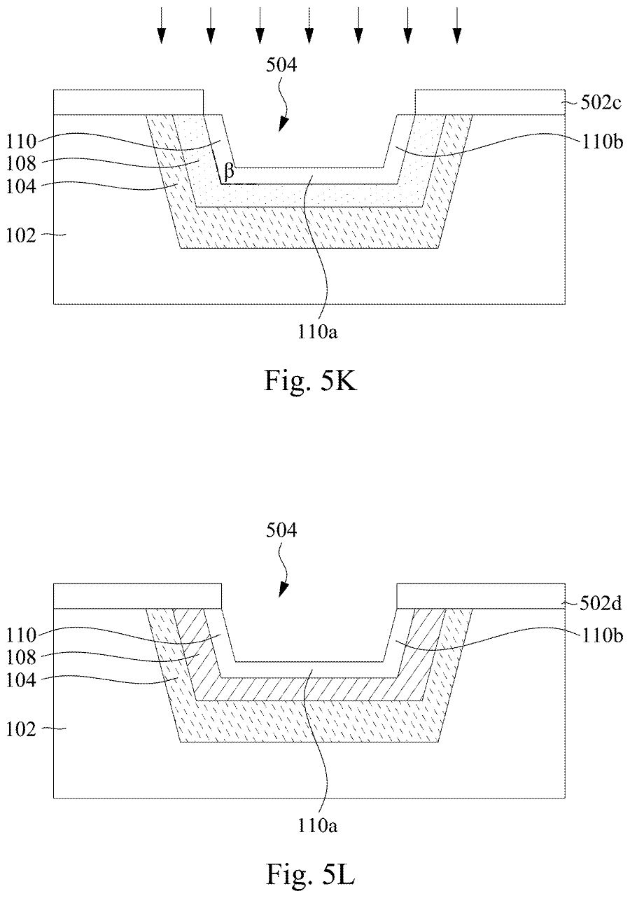

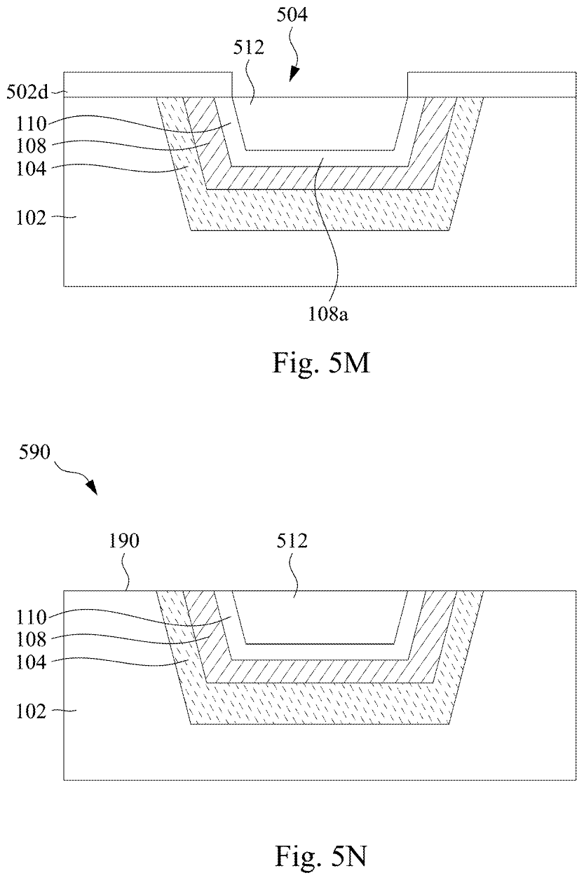

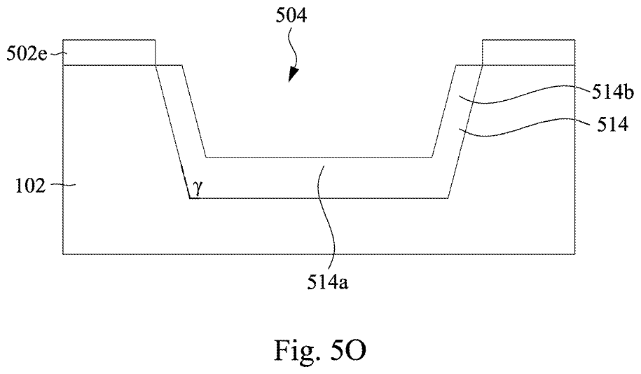

As will be described below in greater detail, at least two examples of operation 202 (i.e., 202a and 202b) are shown in FIGS. 3A and 3B, respectively, and details of the operations 202a and 202b will be described below with reference to FIGS. 3A and 3B. An example of the base structure will be described below with reference to FIG. 5N.

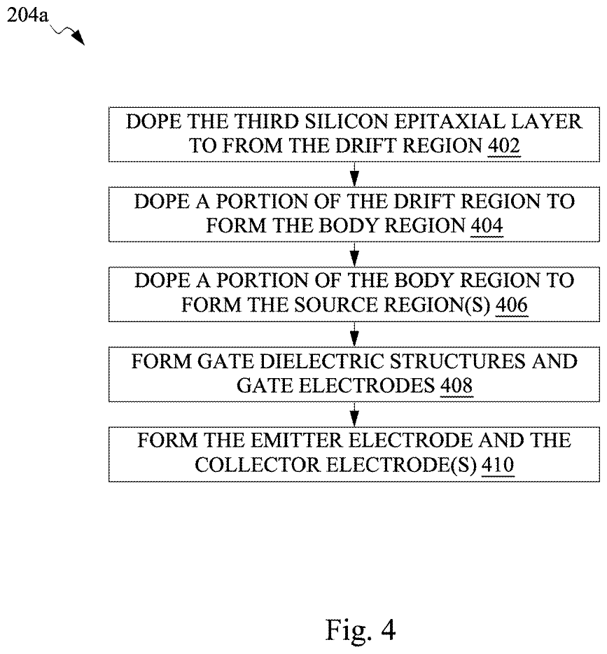

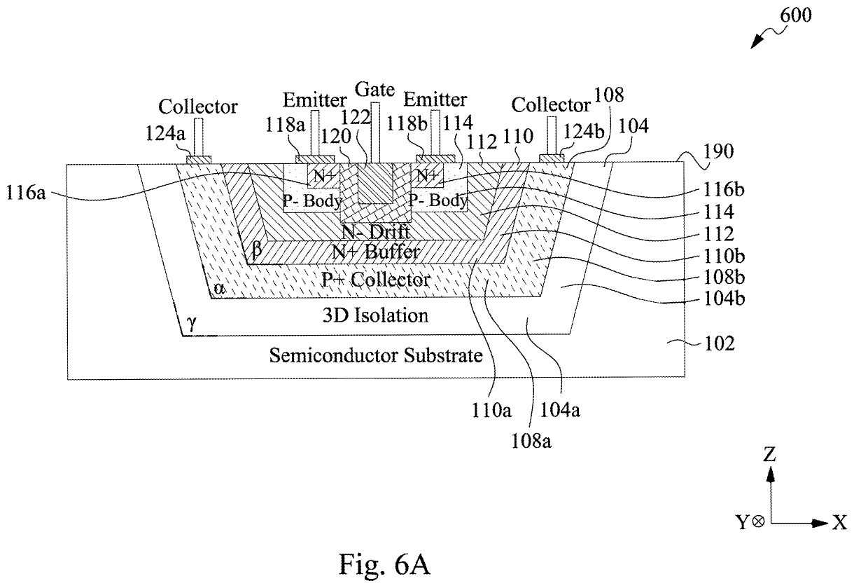

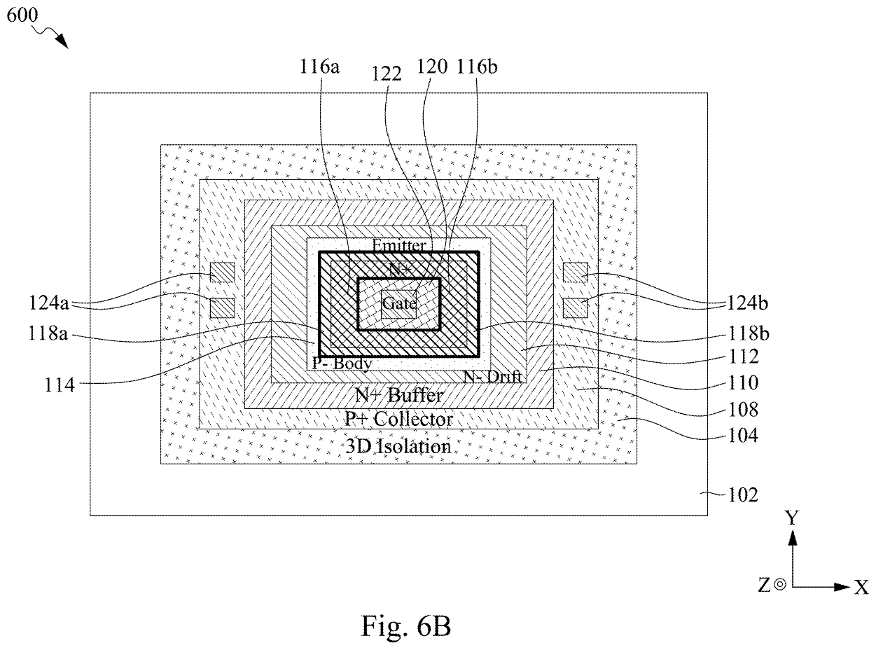

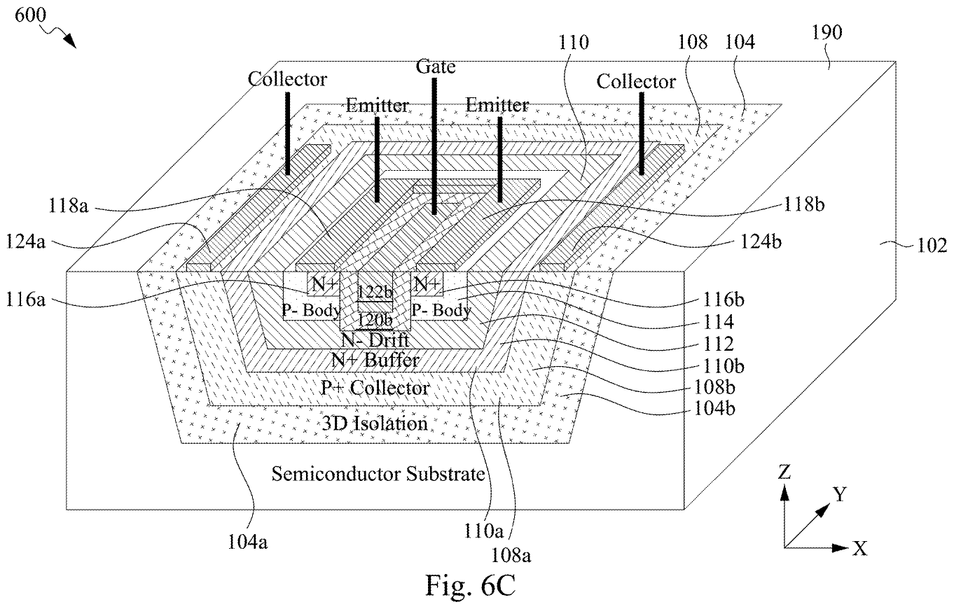

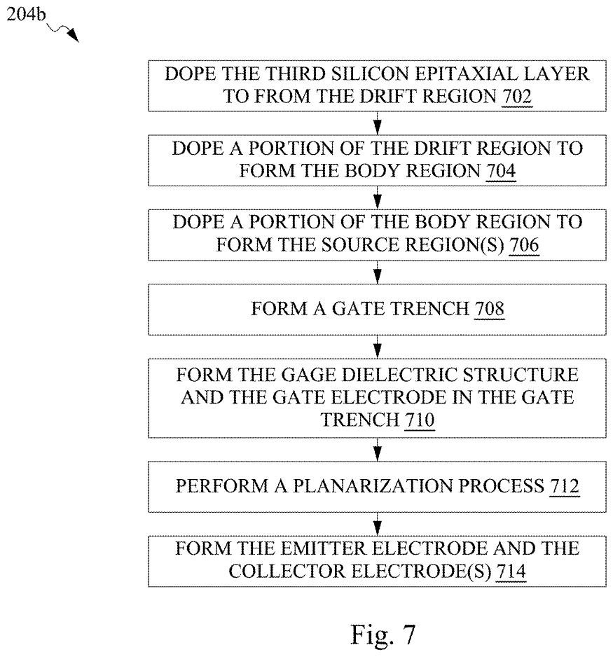

At operation 204, an IGBT is fabricated on the base structure. As will be described below in greater detail, at least two examples of operation 204 (i.e., 204a and 204b) are shown in FIGS. 4 and 7, respectively, and details of the operations 204a and 204b will be described below with reference to FIGS. 4 and 7. An example of the IGBT fabricated using operation 204a shown in FIG. 4 is the IGBT 100 shown in FIGS. 1A-1C, which is a surface-gate IGBT. An example of the IGBT fabricated using operation 204b shown in FIG. 7 is the IGBT 600 shown in FIGS. 6A-6C, which is a trench-gate IGBT.

FIG. 3A is a flowchart diagram illustrating an example of the operation 202 shown in FIG. 2 in accordance with some embodiments. FIGS. 5A-5N are cross-sectional diagrams illustrating the structure, at various stages, fabricated using the example operation 202a shown in FIG. 3A.

At operation 302, a semiconductor substrate is provided. As mentioned above, the semiconductor substrate is a silicon substrate in one implementation. It should be understood that other types of substrate may be employed as well in other implementations.

At operation 304, a trench is formed in the semiconductor substrate. In one implementation, the semiconductor substrate is selectively etched to form the trench. In one example, the trench is etched by etching the area of the semiconductor substrate that is left exposed by the first mask pattern. In one implementation, the first mask pattern is a photoresist mask pattern. In another implementation, the first mask pattern is a hard mask pattern, and the hard mask pattern may include silicon oxide, silicon nitride, silicon oxynitride, or combinations thereof. In one implementation, the semiconductor substrate is etched using wet etching. In another implementation, the semiconductor substrate is etched using dry etching. In one example, the semiconductor substrate is etched using plasma etching.

In the example shown in FIG. 5A, the semiconductor substrate 102 has an area that is left exposed by the first mask pattern 502a. The geometry of the area that is left exposed corresponds to the trench to be formed.

In the example shown in FIG. 5B, the trench 504 is formed by etching the semiconductor substrate 102. After the semiconductor substrate 102 is etched, the trench 504 has a bottom and sidewalls. The bottom and sidewalls define the angle α shown in FIG. 1A. In some embodiments, the angle α is larger than 85 degrees. In one example, the angle α is 90 degrees. In another example, the angle α is 100 degrees. In yet another example, the angle α is 110 degrees. In still another example, the angle α is 120 degrees.

At operation 306, an oxygen-implanted layer is formed. In one implementation, an opening is defined using the second mask pattern, which has a larger opening than the first mask pattern used at operation 304. The difference between these two mask patterns corresponds to the geometry (in the X-Y plane) of the 3D isolation region 104 shown in FIG. 1B. In one implementation, the second mask pattern is a photoresist mask pattern. In another implementation, the second mask pattern is a hard mask pattern, and the hard mask pattern may include silicon oxide, silicon nitride, silicon oxynitride, or combinations thereof.

The area of the semiconductor substrate left exposed by the second mask pattern is implanted with oxygen. As a result, oxygen is implanted into the semiconductor substrate below the surface of the bottom and sidewalls of the trench. Depending on the implant energy and duration, the thickness of the oxygen-implanted layer may be adjusted. The thickness of the oxygen-implanted layer is defined as a portion below the top surface with oxygen concentration above a predetermined amount. In one example, the oxygen concentration ranges from 5×10¹⁵ cm⁻² to 5×10¹⁸ cm⁻². It should be understood that other oxygen concentration values can be employed in other examples.

As shown in the example in FIGS. 5C and 5D, the oxygen-implanted layer 506 is formed after operation 306. The second mask pattern 502b has a larger opening than the first mask pattern 502a shown in FIGS. 5A-5B. The oxygen-implanted layer 506 corresponds to the 3D isolation region 104 shown in FIG. 1A. The oxygen-implanted layer 506 has a bottom portion 506a and the sidewall portion 506b. The sidewall portion 506b is disposed on the sidewall portion of the trench 504. The sidewall portion 506b and the bottom portion 506a define the angle γ shown in FIG. 1A. In some embodiments, the angle γ is larger than 85 degrees. In one example, the angle γ is 90 degrees. In another example, the angle γ is 100 degrees. In yet another example, the angle γ is 110 degrees. In still another example, the angle γ is 120 degrees.

At operation 308, a first silicon epitaxial layer is formed on the oxygen-implanted layer. In one implementation, an opening is defined using the first mask pattern used at operation 304, which has a smaller opening than the second mask pattern used at operation 306. The first silicon epitaxial layer is epitaxially grown on the oxygen-implanted layer. In some implementations, the first silicon epitaxial layer is epitaxially grown using chemical vapor deposition (CVD) techniques (e.g., metal-organic chemical vapor deposition (MOCVD), atmospheric-pressure CVD (APCVD), low-pressure CVD (LPCVD), ultra-high-vacuum CVD (UHVCVD)), molecular beam epitaxy (MBE), atomic layer deposition (ALD), other suitable techniques, or combinations thereof.

In the example shown in FIG. 5E, the first mask pattern 502a covers the top surface of the sidewall portion 506b of the oxygen-implanted layer 506, preventing the first silicon epitaxial layer from forming thereon.

In the example shown in FIG. 5F, the first silicon epitaxial layer 508 is formed on the oxygen-implanted layer 506. The first silicon epitaxial layer 508 corresponds to the collector region 108 shown in FIG. 1A. The first silicon epitaxial layer 508 has a bottom portion 508a and the sidewall portion 508b. The sidewall portion 508b and the bottom portion 508a define the angle α shown in FIG. 1A. In some embodiments, the angle α is larger than 85 degrees. In one example, the angle α is 90 degrees. In another example, the angle α is 100 degrees. In yet another example, the angle α is 110 degrees. In still another example, the angle α is 120 degrees.

At operation 310, a first annealing process is performed. In one implementation, the first annealing process is a thermal annealing process. In one example, the temperature of the thermal annealing process ranges from 900 °C to 1100 °C. After the first annealing process, the oxygen in the oxygen-implanted layer, which is introduced at operation 306, reacts with the silicon in the oxygen-implanted layer to form silicon dioxide. As a result, the oxygen-implanted layer transforms to a silicon dioxide layer, which is the 3D isolation region 104 shown in FIG. 1A.

In the example shown in FIG. 5G, the oxygen-implanted layer 506 shown in FIG. 5F transforms to the 3D isolation region 104. The 3D isolation region 104 includes the bottom portion 104a and the sidewall portion 104b.

At operation 312, the first silicon epitaxial layer is doped. In one embodiment, the silicon epitaxial is heavily doped. In one implementation, the silicon epitaxial is heavily doped using ion implantation. In one example, the dopant concentration ranges from 1×10¹⁶ cm⁻² to 1×10¹⁸ cm⁻². It should be understood that other dopant concentration values can be employed in other examples. After operation 312, the first silicon epitaxial layer transforms to the collector region 108 shown in FIG. 1A.

In the example shown in FIG. 5H, the first silicon epitaxial layer 508 shown in FIG. 5G is doped. After operation 312, the first silicon epitaxial layer 508 shown in FIG. 5G transforms to the collector region 108 shown in FIG. 5H. The collector region 108 includes the bottom portion 108a and the sidewall portion 108b. The sidewall portion 108b and the bottom portion 108a define the angle α shown in FIG. 1A. In some embodiments, the angle α is larger than 85 degrees. In one example, the angle α is 90 degrees. In another example, the angle α is 100 degrees. In yet another example, the angle α is 110 degrees. In still another example, the angle α is 120 degrees. In the example shown in FIG. 5H, the collector region is p-type and heavily doped (i.e., p+), and the dopant is boron, aluminum, gallium, or indium.

At operation 314, a second silicon epitaxial layer is formed on the collector region. In one implementation, an opening is defined using the third mask pattern, which has a smaller opening than the first mask pattern used at, for example, operation 312. The opening of the third mask pattern corresponds to the buffer region 110 shown in FIG. 1B. The second silicon epitaxial layer is epitaxially grown on the collector region. In some implementations, the second silicon epitaxial layer is epitaxially grown using CVD techniques (e.g., MOCVD, APCVD, LPCVD, UHVCVD), MBE, ALD, other suitable techniques, or combinations thereof.

In the example shown in FIG. 5I, the third mask pattern 502c covers the top surface of the sidewall portion 108b of the collector region 108, preventing the second silicon epitaxial layer from forming thereon.

In the example shown in FIG. 5J, the second silicon epitaxial layer 510 is formed on the collector region 108. The second silicon epitaxial layer 510 corresponds to the buffer region 110 shown in FIG. 1A. The second silicon epitaxial layer 510 has a bottom portion 510a and the sidewall portion 510b. The sidewall portion 510b and the bottom portion 510a define the angle β shown in FIG. 1A. In some embodiments, the angle β is larger than 85 degrees. In one example, the angle β is 90 degrees. In another example, the angle β is 100 degrees. In yet another example, the angle β is 110 degrees. In still another example, the angle β is 120 degrees.

At operation 316, the second silicon epitaxial layer is doped. In one embodiment, the second silicon epitaxial is heavily doped. In one implementation, the second silicon epitaxial is heavily doped using ion implantation. In one example, the dopant concentration is between 1×10¹⁶ cm⁻² and 1×10¹⁸ cm⁻². It should be understood that other dopant concentration values can be employed in other examples. After operation 316, the second silicon epitaxial layer transforms to the buffer region 110 shown in FIG. 1A.

In the example shown in FIG. 5K, the second silicon epitaxial layer 510 shown in FIG. 5J is doped. After operation 316, the second silicon epitaxial layer 510 shown in FIG. 5J transforms to the buffer region 110 shown in FIG. 5K. The buffer region 110 includes the bottom portion 110a and the sidewall portion 110b. The sidewall portion 110b and the bottom portion 110a define the angle β shown in FIG. 1A. In the example shown in FIG. 5K, the buffer region 110 is n-type and heavily doped (i.e., n+), and the dopant is phosphorus, arsenic, antimony, or bismuth. As explained above, the buffer region 110 exists when the IGBT 100 is a punch-through (PT) IGBT. For a non-punch-through (NPT) IGBT, the processes related to the buffer region are not performed.

At operation 318, the third silicon epitaxial layer is formed on the buffer region. In one implementation, an opening is defined using the fourth mask pattern, which has a smaller opening than the third mask pattern used at, for example, operation 314. The opening of the fourth mask pattern corresponds to the drift region 112 shown in FIG. 1B. The third silicon epitaxial layer is epitaxially grown on the buffer region. In some implementations, the third silicon epitaxial layer is epitaxially grown using CVD techniques (e.g., MOCVD, APCVD, LPCVD, UHVCVD), MBE, ALD, other suitable techniques, or combinations thereof.

In the example shown in FIG. 5L, the fourth mask pattern 502d covers the top surface of the sidewall portion 110b of the buffer region 110, preventing the third silicon epitaxial layer from forming thereon.

In the example shown in FIG. 5M, the third silicon epitaxial layer 512 is formed on the buffer region 110. The third silicon epitaxial layer 512 corresponds to the drift region 112 (a portion of it is used to form the body region 114, the source regions 116a and 116b) shown in FIG. 1A. The third silicon epitaxial layer 512 fills the trench 504.

At operation 320, a chemical-mechanical planarization (CMP) process is performed. The CMP process is performed on the top surface of the semiconductor substrate. After operation 320, the portion of the third silicon epitaxial layer that is outside the trench or above the top surface of the semiconductor substrate is removed.

At operation 322, a second annealing process is performed. In one implementation, the second annealing process is a thermal annealing process. In one example, the temperature of the thermal annealing process ranges from 900 °C to 1100 °C. After the second annealing process, the dopants in the collector region and the buffer region are activated, and the structural defects and stress are reduced. It should be understood that other benefits may be achieved after the second annealing process.

In the example shown in FIG. 5N, the dopants in the collector region 108 and the buffer region 110 are activated. As such, a base structure 590, as shown in FIG. 5N, is fabricated. The base structure 590 includes the 3D isolation region 104, the collector region 108, the buffer region 110, and the third silicon epitaxial layer 512. The base structure 590 provides a platform to fabricate IGBTs including both surface-gate IGBTs and trench-gate IGBTs.

FIG. 3B is a flowchart diagram illustrating another example of the operation 202 shown in FIG. 2 in accordance with some embodiments. FIG. 5O is a cross-sectional diagram illustrating the structure, at one stage, fabricated using the example method 202b shown in FIG. 3B.

The example operation 202b shown in FIG. 3B is similar to the example operation 202a shown in FIG. 3A. The major difference is that the oxygen of the 3D isolation region 104 is introduced during the epitaxial growth of an oxygen-containing silicon epitaxial layer, instead of using oxygen implantation as shown in FIG. 5D. Another difference is that the second silicon epitaxial layer is formed and doped in one step, instead of epitaxially growing the second silicon epitaxial layer and subsequently doing it. The description below will focus more on these differences, and the details of the identical or similar operations will not be repeated.

At operation 302, a semiconductor substrate is provided. Operation 302 is identical to operation 302 shown in FIG. 3A. As mentioned above, the semiconductor substrate is a silicon substrate in one implementation.

At operation 304, a trench is formed in the semiconductor substrate. Operation 304 is identical to operation 304 shown in FIG. 3A. In one implementation, the semiconductor substrate is selectively etched to form the trench. In one example, the trench is etched by etching the area of the semiconductor substrate that is left exposed by the first mask pattern. In one implementation, the first mask pattern is a photoresist mask pattern. In another implementation, the first mask pattern is a hard mask pattern, and the hard mask pattern may include silicon oxide, silicon nitride, silicon oxynitride layer, or combinations thereof. Unlike operation 304 shown in FIG. 3A where the opening of the first mask pattern corresponds to the collector region 108 shown in FIG. 1B, the opening of the first mask pattern used at operation 304 shown in FIG. 3B corresponds to the 3D isolation region 104.

At operation 306′, which is different from operation 306 shown in FIG. 3A, an oxygen-containing silicon epitaxial layer is formed. The oxygen-containing silicon epitaxial layer is epitaxially grown on the trench, and oxygen is introduced as the dopant during the epitaxial growth. In other words, oxygen and silicon are both source materials. In some implementations, the oxygen-containing silicon epitaxial layer is epitaxially grown using CVD techniques (e.g., MOCVD, APCVD, LPCVD, UHVCVD), molecular beam epitaxy (MBE), atomic layer deposition (ALD), other suitable techniques, or combinations thereof.

In the example shown in FIG. 5°, the oxygen-containing silicon epitaxial layer 514 is formed on the trench 504. The opening of the first mask pattern 502e used at operation 304 shown in FIG. 3B corresponds to the geometry of the 3D isolation region 104 shown in FIG. 1B. The oxygen-containing silicon epitaxial layer 514 corresponds to the 3D isolation region 104 shown in FIG. 1A. The oxygen-containing silicon epitaxial layer 514 has a bottom portion 514a and the sidewall portion 514b. The sidewall portion 514b is disposed on the sidewall portion of the trench 504. The sidewall portion 514b and the bottom portion 514a define the angle γ shown in FIG. 1A. In some embodiments, the angle γ is larger than 85 degrees. In one example, the angle γ is 90 degrees. In another example, the angle γ is 100 degrees. In yet another example, the angle γ is 110 degrees. In still another example, the angle γ is 120 degrees.

At operation 308′, which is similar to operation 308 shown in FIG. 3A, a first silicon epitaxial layer is formed on the oxygen-containing silicon epitaxial layer. In one implementation, an opening is defined using the second mask pattern, and the opening of the second mask pattern corresponds to the geometry of the collector region 108 shown in FIG. 1B. The first silicon epitaxial layer is epitaxially grown on the oxygen-containing silicon epitaxial layer. In some implementations, the first silicon epitaxial layer is epitaxially grown using CVD techniques (e.g., MOCVD, APCVD, LPCVD, UHVCVD), MBE, ALD, other suitable techniques, or combinations thereof.

At operation 310, which is identical to operation 310 shown in FIG. 3A, a first annealing process is performed. In one implementation, the first annealing process is a thermal annealing process. In one example, the temperature of the thermal annealing process ranges from 900 °C to 1100 °C. After the first annealing process, the oxygen in the oxygen-containing silicon epitaxial layer, which is introduced at operation 306′, reacts with the silicon in the oxygen-containing silicon epitaxial layer to form silicon dioxide. As a result, the oxygen-containing silicon epitaxial layer transforms to a silicon dioxide layer, which is the 3D isolation region 104 shown in FIG. 1A.

At operation 312, which is identical to operation 312 shown in FIG. 3A, the first silicon epitaxial layer is doped to form the collector region. In one embodiment, the silicon epitaxial is heavily doped. In one implementation, the first silicon epitaxial is heavily doped using ion implantation. In one example, the dopant concentration ranges from 1×10¹⁶ cm⁻² to 1×10¹⁸ cm⁻². It should be understood that other dopant concentration values can be employed in other examples. After operation 312, the first silicon epitaxial layer transforms to the collector region 108 shown in FIG. 1A. In one example, the collector region is p-type and heavily doped (i.e., p+), and the dopant is boron, aluminum, gallium, or indium.

At operation 314′, which is different from operation 314 shown in FIG. 3A, a second silicon epitaxial layer is formed and doped on the collector region. In one implementation, an opening is defined using the third mask pattern, which has a smaller opening than the second mask pattern. The opening of the third mask pattern corresponds to the geometry of the buffer region 110 shown in FIG. 1B. The second silicon epitaxial layer is epitaxially grown on the collector region, and the dopant is introduced as the dopant during the epitaxial growth. In other words, the dopant and silicon are both source materials. In some implementations, the second silicon epitaxial layer is epitaxially grown using CVD techniques (e.g., MOCVD, APCVD, LPCVD, UHVCVD), MBE, ALD, other suitable techniques, or combinations thereof. In one embodiment, the second silicon epitaxial is heavily doped. In one implementation, the second silicon epitaxial is heavily doped using ion implantation. In one example, the dopant concentration is between 1×10¹⁶ cm⁻² and 1×10¹⁸ cm⁻². It should be understood that other dopant concentration values can be employed in other examples. After operation 314′, the second silicon epitaxial layer transforms to the buffer region 110 shown in FIG. 1A. In one example, the buffer region is n-type and heavily doped (i.e., n+), and the dopant is phosphorus, arsenic, antimony, or bismuth. As explained above, the buffer region exists when the IGBT to be fabricated is a punch-through (PT) IGBT.

At operation 318, which is identical to operation 318 shown in FIG. 3A, the third silicon epitaxial layer is formed on the buffer region. In one implementation, an opening is defined using the fourth mask pattern, which has a smaller opening than the third mask pattern used. The opening of the fourth mask pattern corresponds to the geometry of the drift region 112 shown in FIG. 1B. The third silicon epitaxial layer is epitaxially grown on the buffer region. In some implementations, the third silicon epitaxial layer is epitaxially grown using CVD techniques (e.g., MOCVD, APCVD, LPCVD, UHVCVD), MBE, ALD, other suitable techniques, or combinations thereof. The third silicon epitaxial layer fills the trench.

At operation 320, which is identical to operation 320 shown in FIG. 3A, a CMP process is performed. The CMP process is performed on the top surface of the semiconductor substrate. After operation 320, the portion of the third silicon epitaxial layer that is outside the trench or above the top surface of the semiconductor substrate is removed.

At operation 322, which is identical to operation 322 shown in FIG. 3A, a second annealing process is performed. In one implementation, the second annealing process is a thermal annealing process. In one example, the temperature of the thermal annealing process ranges from 900 °C to 1100 °C. After the second annealing process, the dopants in the collector region and the buffer region are activated, and the structural defects and stress are reduced. It should be understood that other benefits may be achieved after the second annealing process.

As such, a base structure, which is identical to the base structure 590 shown in FIG. 5N, is fabricated. The base structure 590 includes the 3D isolation region 104, the collector region 108, the buffer region 110, and the third silicon epitaxial layer 512. The base structure 590 provides a platform to fabricate IGBTs including both surface-gate IGBTs and trench-gate IGBTs.

FIG. 4 is a flowchart diagram illustrating an example of the operation 204 shown in FIG. 2 in accordance with some embodiments. As described above, the example operation 204a relates to the fabrication of a surface-gate IGBT (e.g., the IGBT 100 shown in FIGS. 1A-1C).

In the example shown in FIG. 4, the example operation 204a includes operations 402, 404, 406, 408, and 410. Additional operations may be performed. Also, it should be understood that the sequence of the various operations discussed above with reference to FIG. 4 is provided for illustrative purposes, and as such, other embodiments may utilize different sequences. These various sequences of operations are to be included within the scope of embodiments.

At operation 402, the third silicon epitaxial layer is doped to form the drift region. In one implementation, the third silicon epitaxial layer (e.g., the third silicon epitaxial layer 512) is doped of the second conductive type and lightly doped to form the drift region (e.g., the drift region 112). In the example shown in FIGS. 1A-1C, the drift region is n-type and lightly doped (i.e., n−). In one example, the dopant concentration of the drift region ranges from 1×10¹² cm⁻² to 1×10¹⁴ cm⁻². The doping can be achieved using ion implantation, diffusion, or the like.

At operation 404, a portion of the drift region is doped to form the body region. In one implementation, a portion of the drift region is doped of the first conductive type and lightly doped to form the body region (e.g., the body region 114). In the example shown in FIGS. 1A-1C, the body region 114 is p-type and lightly doped (i.e., p−). In one example, the dopant concentration of the body region ranges from 1×10¹² cm⁻² to 1×10¹⁴ cm⁻². The doping can be achieved using ion implantation, diffusion, or the like.

At operation 406, a portion of the body region is doped to form the source region(s). In one implementation, a portion of the body region is doped of the second conductive type and heavily doped to form the source region(s) (e.g., the source regions 116a and 116b). It should be understood that although two source regions 116a and 116b are shown in the example shown in FIGS. 1A-1C, one source region or more than two source regions can be employed in other examples. In the example shown in FIGS. 1A-1C, the source regions 116a and 116b are n-type and heavily doped (i.e., n+). In one example, the dopant concentration of the source region(s) ranges from 1×10¹⁵ cm⁻² to 5×10¹⁵ cm⁻². The doping can be achieved using ion implantation, diffusion, or the like.

At operation 408, the gate dielectric structures and the gate electrodes are formed. In one implementation, the gate dielectric structures and the gate electrodes are fabricated using the following process flow: forming a gate dielectric layer; forming a gate electrode layer on the gate dielectric layer; and patterning and etching the exposed gate electrode layer and the gate dielectric layer. In the example shown in FIG. 1A, the gate dielectric structures 120a and 120b and the gate electrodes 122a and 122b are formed. It should be understood that although two gate dielectric structures 120a and 120b and two gate electrodes 122a and 122b are shown in the example shown in FIG. 1A, this is not intended to be limiting. One gate dielectric structure or more than two gate dielectric structures may be employed in other embodiments. One gate electrode or more than two gate electrodes may be employed in other embodiments.

At operation 410, the emitter electrode and the collector electrode(s) are formed. In one implementation, the emitter electrode and the collector electrode(s) are formed using the following process flow: forming an inter-layer dielectric (ILD) layer; patterning and etching the exposed ILD layer to form through holes above the place corresponding to the emitter electrode and the collector electrode(s); forming the emitter electrode and the collector electrode(s). It should be understood that the example above is not intended to be limiting. In the example shown in FIG. 1A, the emitter electrode 118 and the collector electrodes 124a and 124b are formed. It should be understood that although one emitter electrode 118 and two collector electrodes 124a and 124b are shown in the example shown in FIG. 1A, this is not intended to be limiting. Multiple emitter electrodes may be employed in other embodiments. One collector electrode or more than two collector electrodes may be employed in other embodiments.

FIG. 6A is a cross-sectional diagram illustrating an example IGBT 600 in accordance with some embodiments. FIG. 6B is a top view of the example IGBT 600 shown in FIG. 6A in accordance with some embodiments. FIG. 6C is a perspective view of the example IGBT 600 shown in FIG. 6A in accordance with some embodiments. In the example shown in FIGS. 6A-6C, the IGBT 600 includes, among other components, a semiconductor substrate 102, a 3D isolation region 104, a collector region 108, a buffer region 110, a drift region 112, a body region 114, two source regions 116a and 116b, two emitter electrode 118a and 118b, a gate dielectric structure 120, a gate electrode 122, and two collector electrodes 124a and 124b.

The semiconductor substrate 102, the 3D isolation region 104, the collector region 108, the buffer region 110, the drift region 112, the body region 114, the collector electrodes 124a and 124b are identical to those shown in FIGS. 1A-1C. However, unlike the IGBT 100 shown in FIGS. 1A-1C, the IGBT 600 shown in FIGS. 6A-6C is a trench-gate IGBT.

The source regions 116a and 116b are connected (or alternatively being regarded as “one-piece”, collectively referred to as “the source region 116”) as shown in FIG. 6B. The source regions 116a and 116b are disposed in the body region 114. The source regions 116a and 116b are encircled by the body region 114 in the horizontal directions. The emitter electrodes 118a and 118b are disposed on the top surface 190 of the semiconductor substrate 102. The emitter electrode 118a is disposed on a portion of the source region 116a and a portion of the body region 114, while the emitter electrode 118b is disposed on a portion of the source region 116b and a portion of the body region 114.

The gate dielectric structure 120 is disposed in a gate trench surrounded by the body region 114 and the source region 116 in the X-Y plane. The gate trench penetrates the source region 116 and the body region 114 in the Z-direction and extends into the drift region 112 in the Z-direction. The gate electrode 122 is disposed in the center region of the gate dielectric structure 120 in the X-Y plane.

Likewise, the 3D isolation region 104 separates the collector region 108, the buffer region 110, the drift region 112, the body region 114, and the source regions 116a and 116b from the semiconductor substrate 102 in both the vertical direction and the horizontal directions. That is, the separation is 3D (i.e., in both the vertical direction and the horizontal directions). Accordingly, the 3D isolation region 104 provides the IGBT 600 with good isolation, without using an expensive SOI substrate.

It should be understood that the conductivity type of the collector region 108, the buffer region 110, the drift region 112, the body region 114, and the source regions 116a and 116b can be the opposite to those shown in FIG. 6A in another example.

In one example, the device depth (i.e., the distance between the bottom surface of the collector region 108 and the top surface 190 of the semiconductor substrate 102 in the Z-direction) ranges from 2 μm to 200 μm. In one example, the thickness (both in the Z-direction and the X-direction) of the collector region 108 ranges from 0.1 μm to 1 μm. In one example, the thickness (both in the Z-direction and the X-direction) of the buffer region 110 ranges from 0.05 μm to 1 μm. In one example, the thickness (both in the Z-direction and the X-direction) of the 3D isolation region 104 is larger than 0.1 μm. In one example, the distance between the buffer region 108 and the collector electrode 124a or 124b in the X-direction is larger than 0.1 μm. In one example, the distance between the drift region 112 and the emitter electrode 118a or 118b in the X-direction is larger than 0.1 μm. It should be understood that the examples above are exemplary rather than limiting.

FIG. 7 is a flowchart diagram illustrating another example of the operation 204 shown in FIG. 2 in accordance with some embodiments. As described above, the example operation 204b relates to the fabrication of a trench-gate IGBT (e.g., the IGBT 600 shown in FIGS. 6A-6C).

In the example shown in FIG. 7, the example operation 204b includes operations 702, 704, 706, 708, 710, 712, and 714. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 702, the third silicon epitaxial layer is doped to form the drift region. In one implementation, the third silicon epitaxial layer (e.g., the third silicon epitaxial layer 512) is doped of the second conductive type and lightly doped to form the drift region (e.g., the drift region 112). In the example shown in FIGS. 6A-6C, the drift region is n-type and lightly doped (i.e., n−). In one example, the dopant concentration of the drift region ranges from 1×10¹² cm⁻² to 1×10¹⁴ cm⁻². The doping can be achieved using ion implantation, diffusion, or the like.

At operation 704, a portion of the drift region is doped to form the body region. In one implementation, a portion of the drift region is doped of the first conductive type and lightly doped to form the body region (e.g., the body region 114). In the example shown in FIGS. 6A-6C, the body region 114 is p-type and lightly doped (i.e., p−). In one example, the dopant concentration of the body region ranges from 1×10¹² cm⁻² to 1×10¹⁴ cm⁻². The doping can be achieved using ion implantation, diffusion, or the like.

At operation 706, a portion of the body region is doped to form the source region(s). In one implementation, a portion of the body region is doped of the second conductive type and heavily doped to form the source region(s) (e.g., the source region 116). In the example shown in FIGS. 6A-6C, the source regions 116a and 116b are n-type and heavily doped (i.e., n+). In one example, the dopant concentration of the source region(s) ranges from 1×10¹⁵ cm⁻² to 5×10¹⁵ cm⁻². The doping can be achieved using ion implantation, diffusion, or the like.

At operation 708, a gate trench is formed. The gate trench penetrates through the source region(s) and the body region in the Z-direction and extends into the drift region in the Z-direction. In one example, the gate trench is located at the center of the source region(s) and the body region in the X-Y plane. In one implementation, the gate trench is formed by etching the exposed portion of the source region and the body region.

At operation 710, the gate dielectric structure and the gate electrode are formed in the gate trench. In one implementation, the gate dielectric structure is formed in the gate trench, and the gate electrode is formed on the gate dielectric structure. The gate dielectric structure and the gate electrode fill the entire gate trench. In the example shown in FIG. 6A, the gate dielectric structure 120 and the gate electrode 122 are formed.

At operation 712, a planarization process is performed. After the planarization process is performed, the portion of the gate dielectric structure and the gate electrode that is above outside the gate trench or above the top surface of the semiconductor surface is removed. In one implementation, the planarization process is a CMP process. In another implementation, the planarization process is an etching process.

At operation 714, the emitter electrode and the collector electrode(s) are formed. In the example shown in FIG. 6A, the emitter electrodes 118a and 118b and the collector electrodes 124a and 124b are formed.

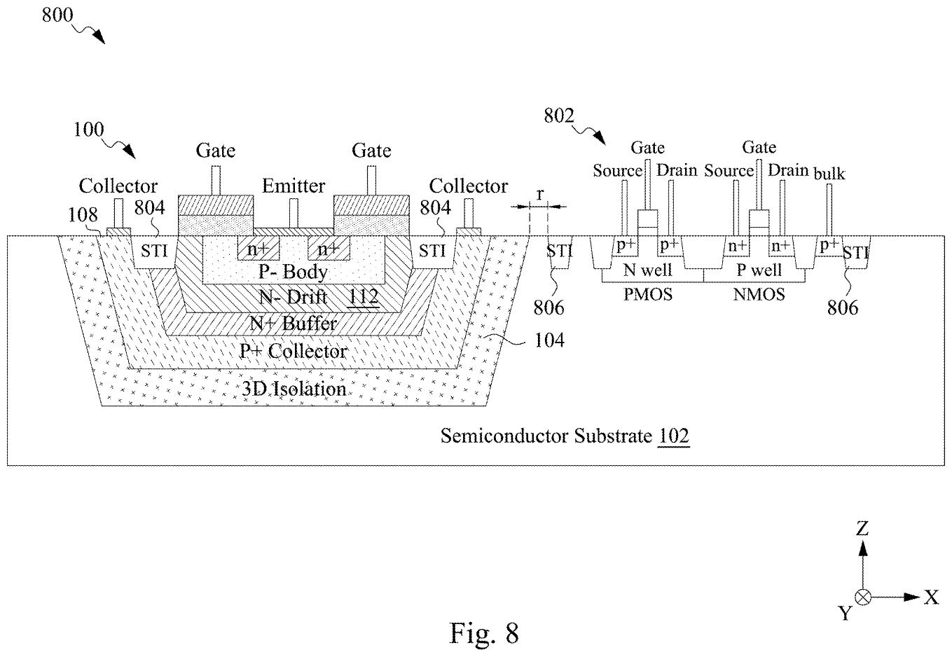

FIG. 8 is a diagram illustrating a chip 800 in accordance with some embodiments. The IGBT 100 shown in FIGS. 1A-1C and the IGBT 600 shown in FIGS. 6A-6C can be integrated and electrically connected with other devices on a single chip to form an IC because the IGBT 100 or 600 are fabricated on a silicon substrate and compatible with silicon process flows. In the example shown in FIG. 8, the chip 800 is formed on the semiconductor substrate 102 (e.g., a silicon substrate). The chip 800 includes the IGBT 100 and the IC 802. Both the IGBT 100 and the IC 802 are embedded in the semiconductor substrate 102. The IGBT 100 shown in FIG. 8 is similar to the IGBT shown in FIGS. 1A-1C except that intra-device shallow trench isolation (STI) structures 804 are formed between the collector region 108 and the drift region 112 in the X-direction. The IC 802 is lateral to the IGBT 100 in the X-direction, and the IGBT 100 and the IC 802 are separated by an inter-device STI structure 806. The distance between the 3D isolation region 104 and the inter-device STI structure 806 in the X-direction is a first distance r. In one embodiment, the first distance r is larger than 5 μm. The 3D isolation region 104 of the IGBT 100 and the inter-device STI structure 806 collectively isolate the IGBT 100 and the IC 802.

In the example shown in FIG. 8, the IC 802 includes CMOS devices comprised of PMOS devices and NMOS devices. It should be understood that this example is exemplary rather than limiting, and the IC 802 can include other devices such as laterally-diffused metal-oxide-semiconductor (LDMOS) devices, high-voltage metal-oxide-semiconductor (HVMOS) devices, etc.

In accordance with some aspects of the disclosure, an insulated gate bipolar transistor (IGBT) is provided. The IGBT includes: a semiconductor substrate having a top surface extending in a horizontal plane; a three-dimensional (3D) isolation region comprising a silicon compound, the 3D isolation region having a bottom portion and a sidewall portion; a collector region of a first conductive type disposed on the 3D isolation region; a buffer region of a second conductive type opposite to the first conductive type disposed on the collector region; a drift region of the second conductive type disposed on the buffer region; a body region of the first conductive type disposed in the drift region; and at least one source region of the second conductive type disposed in the body region. The 3D isolation region and the top surface of the semiconductor substrate enclose the collector region, the buffer region, the drift region, the body region, and the at least one source region.

In accordance with some aspects of the disclosure, a chip is provided. The chip includes an insulated gate bipolar transistor (IGBT) and an integrated circuit (IC). The IGBT includes: a semiconductor substrate having a top surface extending in a horizontal plane; a three-dimensional (3D) isolation region comprising a silicon compound, the 3D isolation region having a bottom portion and a sidewall portion; a collector region of a first conductive type disposed on the 3D isolation region; a buffer region of a second conductive type opposite to the first conductive type disposed on the collector region; a drift region of the second conductive type disposed on the buffer region; a body region of the first conductive type disposed in the drift region; and at least one source region of the second conductive type disposed in the body region. The sidewall portion separates the collector region, the buffer region, the drift region, the body region, and the at least one source region from the semiconductor substrate in the horizontal directions, while the bottom portion separates the collector region, the buffer region, the drift region, the body region, and the at least one source region from the semiconductor substrate in a vertical direction. The IC is embedded in the semiconductor substrate.

In accordance with some aspects of the disclosure, a method for fabricating an insulated gate bipolar transistor (IGBT) is provided. The method includes: providing a semiconductor substrate having a top surface extending in a horizontal plane; forming a three-dimensional (3D) isolation region comprising a silicon compound, the 3D isolation region having a bottom portion and a sidewall portion; forming a collector region of a first conductive type disposed on the 3D isolation region; forming a buffer region of a second conductive type opposite to the first conductive type disposed on the collector region; forming a drift region of the second conductive type disposed on the buffer region; forming a body region of the first conductive type disposed in the drift region; and forming at least one source region of the second conductive type disposed in the body region, wherein the 3D isolation region and the top surface of the semiconductor substrate enclose the collector region, the buffer region, the drift region, the body region, and the at least one source region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an insulated gate bipolar transistor (IGBT), the method comprising:
providing a semiconductor substrate having a top surface extending in a horizontal plane;
forming a three-dimensional (3D) isolation region comprising a silicon compound, the 3D isolation region having a bottom portion and a sidewall portion;
forming a collector region of a first conductive type disposed on the 3D isolation region;
forming a buffer region of a second conductive type opposite to the first conductive type disposed on the collector region;
forming a drift region of the second conductive type disposed on the buffer region;
forming a body region of the first conductive type disposed in the drift region; and
forming at least one source region of the second conductive type disposed in the body region, and
wherein the 3D isolation region and the top surface of the semiconductor substrate enclose the collector region, the buffer region, the drift region, the body region, and the at least one source region.

2. The method of claim 1, wherein forming the 3D isolation region comprises:
forming the sidewall portion to extend upwardly from a perimeter of the bottom portion such that the sidewall portion reaches the top surface of the semiconductor substrate.

3. The method of claim 2, wherein the sidewall portion and the bottom portion define an angle that is between 85 degrees and 120 degrees.

4. The method of claim 2, wherein the sidewall portion and the bottom portion define a round corner.

5. The method of claim 4, wherein a radius of the round corner is larger than 0.05 μm.

6. The method of claim 1, wherein the sidewall portion is formed to encircle the collector region, the buffer region, the drift region, the body region, and the at least one source region in the horizontal plane.

7. The method of claim 1, wherein forming the 3D isolation region comprises:
forming a trench in the semiconductor substrate, the trench having a bottom and sidewalls corresponding to the bottom portion and the sidewall portion of the 3D isolation region.

8. The method of claim 1, wherein forming the drift region comprises forming a silicon epitaxial layer, and wherein the method further comprises:
performing a chemical-mechanical planarization (CMP) process on the top surface of the semiconductor substrate to remove an excess portion of the silicon epitaxial layer.

9. A method for manufacturing a semiconductor device, the method comprising:
providing a silicon substrate having a top surface;
forming a trench in the silicon substrate;
forming an oxygen-implanted layer having a bottom portion on a bottom of the trench and a sidewall portion on sidewalls of the trench;
epitaxially growing a first silicon epitaxial layer on the oxygen-implanted layer;
performing a first thermal annealing process to convert the oxygen-implanted layer into a three-dimensional (3D) isolation region comprising silicon dioxide; and
sequentially forming a plurality of active device regions over the first silicon epitaxial layer, and
wherein the 3D isolation region and the top surface of the silicon substrate encapsulate the first silicon epitaxial layer and the plurality of active device regions.

10. The method of claim 9, wherein forming the trench comprises:
selectively etching the silicon substrate using a first mask pattern.

11. The method of claim 10, wherein forming the oxygen-implanted layer comprises:
defining an opening using a second mask pattern, wherein the second mask pattern has a larger opening than the first mask pattern.

12. The method of claim 9, wherein the first thermal annealing process is performed at a temperature ranging from 900 °C to 1100 °C.

13. The method of claim 9, further comprising:
doping the first silicon epitaxial layer to form a collector region of a first conductive type, wherein the plurality of active device regions sequentially formed over the collector region includes a buffer region, a drift region, a body region, and at least one source region.

14. The method of claim 13, wherein the first silicon epitaxial layer is doped using ion implantation with a dopant selected from the group consisting of boron, aluminum, gallium, and indium, and wherein a dopant concentration of the collector region ranges from 1×10¹⁶ cm⁻² to 1×10¹⁸ cm⁻².

15. A method for fabricating an insulated gate bipolar transistor (IGBT), the method comprising:
forming a trench in a semiconductor substrate;
epitaxially growing an oxygen-containing silicon epitaxial layer within the trench, wherein oxygen and silicon are both used as source materials during the epitaxial growth;
epitaxially growing a first silicon epitaxial layer on the oxygen-containing silicon epitaxial layer;
performing an annealing process such that the oxygen and the silicon in the oxygen-containing silicon epitaxial layer react to form a three-dimensional (3D) isolation region comprising silicon dioxide;
doping the first silicon epitaxial layer to form a collector region; and
forming a buffer region, a drift region, a body region, and at least one source region over the collector region.

16. The method of claim 15, wherein forming the buffer region comprises:
epitaxially growing a second silicon epitaxial layer on the collector region while concurrently introducing a dopant during the epitaxial growth such that the dopant and silicon are both source materials.

17. The method of claim 16, wherein the dopant introduced during the epitaxial growth of the second silicon epitaxial layer is selected from the group consisting of phosphorus, arsenic, antimony, and bismuth.

18. The method of claim 15, wherein the oxygen-containing silicon epitaxial layer is epitaxially grown using chemical vapor deposition (CVD), molecular beam epitaxy (MBE), or atomic layer deposition (ALD).

19. The method of claim 15, further comprising:
applying a mask pattern to define the trench, the mask pattern having an opening corresponding to a geometry of the 3D isolation region.

20. The method of claim 15, wherein the 3D isolation region has a bottom portion and a sidewall portion, the sidewall portion extending upwardly to reach a top surface of the semiconductor substrate to isolate the collector region, the buffer region, the drift region, the body region, and the at least one source region.
